(19) United States
(12) Patent Application Publication
(10) Pub. No.: US 2026/0333529 A1
(43) Pub. Date: Oct. 22, 2026

(54) GRAPHITE ELECTRODE, ELECTRODE DEVICE AND ELECTRODE, AND METHOD FOR PRODUCING QUARTZ GLASS CRUCIBLE

(71) Applicant: SHIN-ETSU QUARTZ PRODUCTS CO., LTD., Tokyo (JP)

(72) Inventors: Yu ISHIHARA, Echizen-shi (JP); Shu YAKUWA, Echizen-shi (JP)

(73) Assignee: SHIN-ETSU QUARTZ PRODUCTS CO., LTD., Tokyo (JP)

(21) Appl. No.: 19/115,894

(22) PCT Filed: Sep. 28, 2023
(86) PCT No.: PCT/JP2023/035498

§ 371 Date: Mar. 27, 2025

(30) Foreign Application Priority Data
Sep. 30, 2022 (JP) 2022-157255
Aug. 21, 2023 (JP) 2023-134195

(51) Int. Cl. H05B 7/085; H05B 7/101; H05B 7/14

(52) U.S. Cl. CPC H05B 7/085; H05B 7/101; H05B 7/14

(57) ABSTRACT

A graphite electrode to be used for arc discharge to produce a quartz crucible, including: a graphite electrode body and a joint protruding from the graphite electrode body, the graphite electrode being able to be coupled to an electrode device for energizing the graphite electrode via the joint, wherein the joint is shaped to be knocked in and coupled to the electrode device.

### TECHNICAL FIELD

The present invention relates to a graphite electrode, an electrode device and an electrode, as well as a method for producing a quartz glass crucible. In particular, the present invention relates to a graphite electrode to be used for arc discharge to produce a quartz glass crucible, an electrode device, and an electrode formed by coupling the graphite electrode to the electrode device.

### BACKGROUND ART

Most of silicon single crystals used as a substrate of a single crystal semiconductor material are produced by a so-called Czochralski method, which is a production method including: melting polycrystalline silicon in a quartz glass crucible; bringing the same into contact with a seed crystal; and thereafter performing crystal growth. Depending on a production method thereof, there are several types of quartz glass crucibles used for this production method of silicon single crystals. In practice, a quartz glass crucible is used, which is produced by filling silicon dioxide powder (quartz powder as a raw material) along an inner peripheral surface of a rotatable hollow mold, and heating and melting the silicon dioxide powder by arc discharge using a graphite electrode while rotating the mold. Many implementations of a graphite electrode used for arc discharge to produce a quartz glass crucible have been disclosed (for example, Patent Documents 1 to 6).

This graphite electrode for use is coupled to an electrode device (for example, made of copper) for energization (see Patent Documents 1 to 6). As a connection method, the graphite electrode is coupled to the electrode device, typically by screwing together a male screw disposed in the graphite electrode and a female screw disposed in the electrode device.

FIG. 2 shows a schematic illustration in a case of threadedly engaging a graphite electrode with an electrode device. As shown in FIG. 2(a), a graphite electrode 111 is provided with a joint 114 in a graphite electrode body 112, where a male thread shape is formed in the joint 114. An external form of the graphite electrode body 112 includes various shapes such as a cylindrical shape.

Moreover, as shown in FIG. 2(b), a holder (a concave connecting unit formed into a recessed shape) 126 is formed in an electrode device 121, where a female thread shape is formed in the holder 126 so as to be threadedly engaged with the joint 114 of the graphite electrode 111. An external form of the electrode device 121 includes various shapes such as a cylindrical shape. The graphite electrode 111 and the electrode device 121 are coupled to each other by threadedly engaging the joint 114 with the holder 126 to form an electrode 131, as shown in FIG. 2(c).

### CITATION LIST

### Patent Literature

Patent Document 1: JP H08-34628 A
Patent Document 2: JP 2016-11238 A
Patent Document 3: JP 2010-180123 A
Patent Document 4: JP 2017-65962 A
Patent Document 5: JP 2003-92179 A
Patent Document 6: JP 2009-161362 A

### SUMMARY OF INVENTION

### Technical Problem

As described above, a graphite electrode is conventionally coupled to an electrode device by threaded engagement. However, the threaded engagement requires a high processing cost for graphite, and causes an increased production cost for a graphite electrode and ultimately an increased production cost for a quartz glass crucible.

The present invention has been made in view of the above circumstances, and a first object of the present invention is to provide: a graphite electrode that can be used in the same manner as a conventional graphite electrode while allowing reduction of a processing cost; an electrode device to be coupled to such graphite electrode; and an electrode configured with the graphite electrode coupled to the electrode device.

Additionally, a second object of the present invention is to provide a graphite electrode that can be reused with an electrode device having a small concave connecting unit for coupling to the graphite electrode after worn by use with an electrode device having a large concave connecting unit.

### Solution to Problem

The present invention has been made to achieve the above objects, and provides a graphite electrode to be used for arc discharge to produce a quartz crucible. The graphite electrode includes a graphite electrode body and a joint protruding from the graphite electrode body. The graphite electrode is able to be coupled to an electrode device for energizing the graphite electrode via the joint. The joint is shaped to be knocked in and coupled to the electrode device.

Since the graphite electrode of the present invention includes the joint that is shaped to be knocked in and coupled to the electrode device, it is easy to process and thus a processing cost can be reduced as compared with a conventional graphite electrode having a screw thread. Moreover, since the graphite electrode of the present invention can be knocked in and coupled to the electrode device, it can be used in the same manner as a conventional graphite electrode when actually used to produce a quartz crucible.

In this case, the joint of the graphite electrode preferably has approximately a truncated cone shape having a greater diameter on a side of the graphite electrode body than a diameter on a tip side.

The graphite electrode including the joint having such shape is easy to couple to the electrode device.

Furthermore, the joint preferably has a height of 10 mm or more and 40 mm or less and has a tapered shape with an angle of 1° or more and 5° or less in a height direction.

The graphite electrode including the joint having such dimensions is easy to couple to the electrode device.

Furthermore, the present invention provides an electrode device capable of holding the above-described graphite electrode, including a hole-shaped holder to be coupled to the joint of the graphite electrode.

Such electrode device is suitable for coupling to the graphite electrode as described above.

In this case, a ratio of an inner diameter of the holder to an outer diameter of the electrode device is preferably 40% or more and 60% or less.

The electrode device including the holder having such dimension makes it easy not only to knock in and couple the graphite electrode thereto, but also to configure an internal structure of the electrode device to flow a coolant therethrough.

Furthermore, a material for the electrode device preferably includes at least one of gold, silver, copper, and aluminum.

Such material for the electrode device is metal with high malleability and high cooling performance. This makes it easy to knock in and couple the graphite electrode thereto, and is also convenient for cooling the electrode device in use as the electrode.

Furthermore, the present invention provides an electrode configured with any of the above-described graphite electrodes coupled to the electrode device.

This electrode can be configured with the graphite electrode, not threadedly engaged with, but knocked in and coupled to the electrode device. A processing cost for such graphite electrode can be reduced, which in turn can reduce a processing cost for the electrode.

Furthermore, the present invention has been made to achieve the above objects, and provides a graphite electrode to be used for arc discharge to produce a quartz glass crucible. The graphite electrode includes a joint via which the graphite electrode is coupled to an electrode device for energizing the graphite electrode. The joint includes a first joint and a second joint different from the first joint. The second joint is smaller than the first joint. The first joint is shaped to be connectable to a first electrode device, and the second joint is shaped to be connectable to a second electrode device smaller than the first electrode device.

Since the graphite electrode of the present invention includes the second joint smaller than the first joint, it is possible to couple the first joint to the first electrode device to perform arc discharge which wears the graphite electrode, and thereafter couple the second joint to the second electrode device to perform arc discharge again.

In this case, the first joint and the second joint can each have a shape with a screw thread or a cylindrical shape.

A combination of these shapes is suitable for the first joint and the second joint.

Furthermore, the present invention provides an electrode configured with any of the above-described graphite electrodes coupled to the first electrode device. The first electrode device is coupled via the first joint of the graphite electrode and has a space capable of housing the second joint.

Since such electrode has the space inside the electrode device capable of housing the second joint of the graphite electrode, it is possible to couple the graphite electrode including the second joint without any difficulty and perform arc discharge.

Furthermore, the present invention provides a method for producing a quartz glass crucible by using any of the above-described graphite electrodes, including the steps of: coupling the graphite electrode to the first electrode device via the first joint to configure a first electrode; producing a quartz glass crucible by arc discharge using the first electrode; removing the graphite electrode worn due to the arc discharge using the first electrode from the first electrode device; coupling the graphite electrode removed from the first electrode device to the second electrode device via the second joint to configure a second electrode; and producing one or more quartz glass crucibles by arc discharge using the second electrode.

The graphite electrode of the present invention includes the second joint smaller than the first joint as described above, such that after it is worn due to arc discharge performed by coupling the first joint to the first electrode device, arc discharge can be performed again by coupling the second joint to the second electrode device. Accordingly, it is possible to reuse one graphite electrode to produce a plurality of quartz glass crucibles.

### Advantageous Effects of Invention

The graphite electrode according to the first aspect of the present invention includes the joint shaped to be knocked in and coupled to the electrode device. Therefore, it is easy to process, and a processing cost can be reduced as compared with a conventional graphite electrode having a screw thread. Additionally, the graphite electrode of the present invention can be knocked in and coupled to the electrode device, so that it can be used in the same manner as a conventional graphite electrode when actually used to produce a quartz crucible. Further, the electrode device of the present invention is suitable for coupling to such graphite electrode. Yet further, in the electrode of the present invention configured with the graphite electrode coupled to the electrode device, the graphite electrode can be knocked in and coupled to, rather than threadedly engaged with, the electrode device. A processing cost for such graphite electrode can be reduced, which in turn can reduce a processing cost for the electrode.

The graphite electrode according to the second aspect of the present invention includes the second joint smaller than the first joint, such that after it is worn due to arc discharge performed by coupling the first joint to the first electrode device, arc discharge can be performed again by coupling the second joint to the second electrode device. This makes it possible to reuse one graphite electrode to produce a plurality of quartz glass crucibles. Accordingly, it is possible to significantly reduce an electrode cost.

### BRIEF DESCRIPTION OF DRAWINGS

FIG. 1 is a schematic illustration showing a graphite electrode, an electrode device, and an electrode formed by coupling them according to an embodiment of the first aspect of the present invention;

FIG. 2 is a schematic illustration showing one example of a conventional graphite electrode, an electrode device, and an electrode formed by coupling them;

FIG. 3 is a schematic illustration showing a first exemplary implementation of a graphite electrode, an electrode device, and an electrode formed by coupling them according to the second aspect of the present invention;

FIG. 4 is a schematic illustration showing a second exemplary implementation of a graphite electrode, an electrode device, and an electrode formed by coupling them according to the second aspect of the present invention;

FIG. 5 is a schematic illustration showing a third exemplary implementation of a graphite electrode, an electrode device, and an electrode formed by coupling them according to the second aspect of the present invention;

FIG. 6 is a schematic illustration showing a fourth exemplary implementation of a graphite electrode, an electrode device, and an electrode formed by coupling them according to the second aspect of the present invention; and

FIG. 7 is a flow diagram illustrating a method for producing a quartz glass crucible according to an embodiment of the second aspect of the present invention.

### DESCRIPTION OF EMBODIMENTS

Hereinafter, the present invention will be described more specifically. Note that in the present invention, “quartz glass crucible” and “quarts crucible” are synonyms referring to the same subject. To respect the priority of the basic application, terms are basically left as they are in the basic application.

Firstly, a graphite electrode, an electrode device, and an electrode formed by coupling them according to the first aspect of the present invention will be described.

The graphite electrode according to the first aspect of the present invention is a graphite electrode to be used for arc discharge to produce a quartz crucible. The graphite electrode includes a graphite electrode body and a joint protruding from the graphite electrode body. The graphite electrode is able to be coupled to an electrode device for energizing the graphite electrode via the joint. The joint is shaped to be knocked in and coupled to the electrode device.

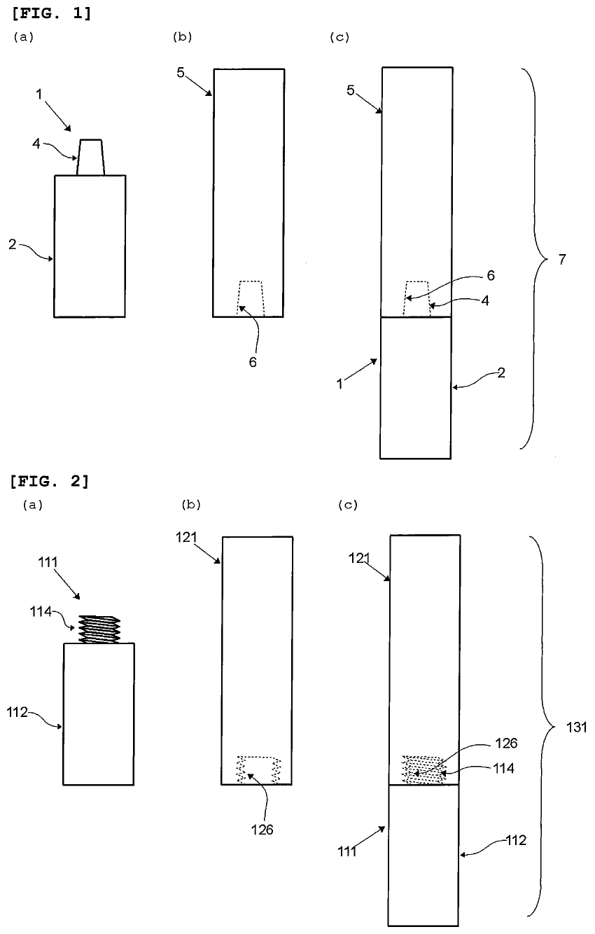

Hereinafter, a specific embodiment of the graphite electrode, the electrode device, and the electrode formed by coupling them of the present invention will be described with reference to the drawings. FIG. 1 shows an implementation of the graphite electrode, the electrode device, and the electrode formed by coupling them of the present invention.

A graphite electrode 1 shown in FIG. 1(a) includes a graphite electrode body 2, and a joint 4 protruding from the graphite electrode body 2. The graphite electrode 1 can be coupled to an electrode device (an electrode device 5 in FIG. 1(b) as described later) for energizing the graphite electrode 1 via the joint 4. Furthermore, the joint 4 is shaped to be knocked in and coupled to the electrode device 5. An external form of the graphite electrode body 2 can be various shapes such as a cylindrical shape.

Moreover, the electrode device 5 as shown in FIG. 1(b) can hold the graphite electrode 1, and includes a hole-shaped holder 6 to be coupled to the joint 4 of the graphite electrode 1.

FIG. 1(c) shows an electrode 7 configured with the graphite electrode 1 coupled to the electrode device 5. When the electrode 7 is formed, the joint 4 of the graphite electrode 1 is coupled to the hole-shaped holder 6 of the electrode device 5. The graphite electrode 1 and the electrode device 5 are coupled to each other by aligning the shapes of the joint 4 and the holder 6 with each other and knocking them with external force.

Since the graphite electrode 1 of the present invention includes the joint 4 that is shaped to be knocked in and coupled to the electrode device 5, it is easy to process and thus a processing cost can be reduced as compared with a conventional graphite electrode having a screw thread. Moreover, since the graphite electrode 1 of the present invention can be knocked in and coupled to the electrode device 5, it can be used in the same manner as a conventional graphite electrode when actually used for producing a quartz crucible.

In the present invention, since the joint 4 of the graphite electrode 1 is knocked in and coupled to the hole-shaped holder 6 of the electrode device 5, an inner size of the holder 6 should be slightly larger than an outer size of the joint 4 due to the necessity of fixation. However, the shape thereof is not limited as long as the graphite electrode 1 can be knocked in and secured thereto.

The joint 4 of the graphite electrode 1 can have various shapes such as cylindrical, conical, and polygonal prism shapes as long as it can be secured to the electrode device 5. For example, it may have a cylindrical shape or a tapered truncated cone shape. These shapes are also referred to as a nipple shape, and the joint 4 having such shape is also referred to as a nipple. Particularly, as shown in FIG. 1(a), the joint 4 preferably has approximately a truncated cone shape having a greater diameter on a side of the graphite electrode body 2 than a diameter on a tip side. Particularly, the joint 4 preferably has a height (length) of 10 mm or more and 40 mm or less and has a tapered shape with an angle of 1° or more and 5° or less in a height direction (note that in FIG. 1, the taper angle is exaggerated). The joint 4 having such truncated cone shape is easy to knock in and secure to the holder 6 of the electrode device 5.

Meanwhile, a ratio of an inner diameter of the holder 6 to an outer diameter of the electrode device 5 is preferably 40% or more and 60% or less. The holder 6 having such dimension makes it easy to knock in and secure the joint 4 of the graphite electrode 1 thereto.

Moreover, the electrode device 5 is preferably cooled by flowing a coolant such as water through the inside thereof. This can provide the electrode device with a cooling capacity to be able to withstand high temperature of arc melting. Also due to the circumstances of the electrode device 5 having such a structure that the cooling water flows through the inside of the electrode device 5, the above ratio of the inner diameter of the holder 6 to the outer diameter of the electrode device 5 is preferably 40% or more and 60% or less.

Moreover, a material for the electrode device 5 preferably includes at least one of gold, silver, copper, and aluminum. These materials are preferable because they are metal with high malleability and high cooling performance, which makes it easy not only to knock in and couple the graphite electrode 1 thereto but also to cool the electrode device 5 in use as the electrode 7.

Moreover, in the hole-shaped holder 6 of the electrode device 5, a depth of the hole of the holder 6 is also preferably 10 mm or more and 40 mm or less, similar to the height of the joint 4 of the graphite electrode 1. Additionally, the tapered shape of the hole of the holder 6 also preferably has an angle of 1° or more and 5° or less in a depth direction, similar to the joint 4 of the graphite electrode 1.

Next, a graphite electrode, and an electrode configured with the graphite electrode coupled to an electrode device according to the second aspect of the present invention will be described.

The graphite electrode according to the second aspect of the present invention is a graphite electrode to be used for arc discharge to produce a quartz glass crucible. The graphite electrode includes a joint via which the graphite electrode is coupled to an electrode device for energizing the graphite electrode. The joint includes a first joint and a second joint different from the first joint. The second joint is smaller than the first joint. The first joint is shaped to be connectable to a first electrode device, and the second joint is shaped to be connectable to a second electrode device smaller than the first electrode device. In this case, the first joint and the second joint can each have a shape with a screw thread or a cylindrical shape.

Hereinafter, specific embodiments of the graphite electrode, the electrode device, and the electrode formed by coupling them according to the second aspect of the present invention will be described with exemplary first to fourth implementations. In the respective implementations, similar components are denoted by the same reference sign.

### First Implementation

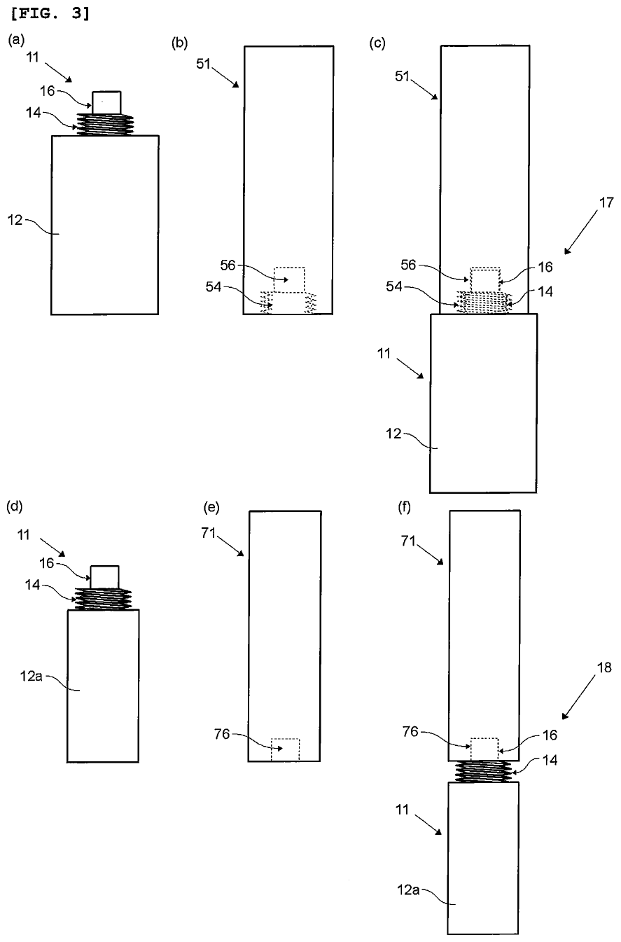

FIG. 3 shows the first implementation of the graphite electrode, the electrode device, and the electrode formed by coupling them of the present invention. In this implementation, the first joint of the graphite electrode has a shape with a screw thread whereas the second joint has a cylindrical shape. Besides the cylindrical shape, the second joint can also employ a conical shape, a polygonal prism shape, or the like, but the cylindrical shape is preferable from the viewpoints of a production cost, mechanical strength, and coupling strength.

A graphite electrode 11 shown in FIG. 3(a) includes a first joint 14 and a second joint 16 adjacent to the first joint 14 in a graphite electrode body 12. These first joint 14 and second joint 16 are coupled to an electrode device (a first electrode device 51 in FIG. 3(b) and a second electrode device 71 in FIG. 3(e) as described later) for energizing the graphite electrode 11. Furthermore, as shown in FIG. 3(a), the second joint 16 is smaller than the first joint 14.

Furthermore, the first joint 14 is shaped to be connectable to the first electrode device 51. In the first implementation, as shown in FIG. 3(a), the first joint 14 has a screw thread. On the other hand, in the first electrode device 51 shown in FIG. 3(b), a concave connecting unit 54 having a female thread shape is formed. The graphite electrode 11 and the first electrode device 51 can be coupled to each other by threadedly coupling the first joint 14 to the concave connecting unit 54, as shown in FIG. 3(c).

Furthermore, the first electrode device 51 can have a space 56 capable of housing the second joint 16 of the graphite electrode 11, as shown in FIG. 3(b). As shown in FIG. 3(c), when coupled via the first joint 14 using the concave connecting unit 54, the first electrode device 51 can house the second joint 16 of the graphite electrode 11 inside the space 56. Therefore, the space 56 is preferably formed to be slightly larger than the second joint 16 of the graphite electrode 11.

As described above, an electrode (first electrode) 17 shown in FIG. 3(c) is configured with the graphite electrode 11 coupled to the first electrode device 51, where the first electrode device 51 is coupled via the first joint 14 of the graphite electrode 11 and has the space 56 capable of housing the second joint 16. Such electrode (first electrode) 17 can be used for arc discharge to produce a quartz glass crucible. After the arc discharge, the graphite electrode body 12 becomes reduced in size due to wear. FIG. 3(d) illustrates a graphite electrode body 12a reduced in size. Additionally, though not shown in FIG. 3(d), as the size becomes smaller, a shape of the graphite electrode body 12a may change.

Moreover, the second joint 16 of the graphite electrode 11 is shaped to be connectable to the second electrode device 71 smaller than the first electrode device 51, as shown in FIG. 3(e). In the first implementation, as shown in FIGS. 3(a) and 3(d), the second joint 16 has a cylindrical shape. Additionally, in the second electrode device 71 shown in FIG. 3(e), a concave connecting unit 76 is formed, in which the second joint 16 can be knocked. The graphite electrode 11 and the second electrode device 71 can be coupled to each other by coupling the second joint 16 to the concave connecting unit 76, as shown in FIG. 3(f). A second electrode 18 configured with the graphite electrode 11 coupled to the second electrode device 71 can be used for arc discharge to produce a quartz glass crucible.

As described above, in general, coupling between the graphite electrode and the electrode device by the knock-in method is used for the relatively small graphite electrode, whereas coupling between the graphite electrode and the electrode device by the threaded engagement is used for the relatively large graphite electrode. Therefore, the first implementation is preferred, where the first joint of the graphite electrode has the shape with the screw thread and the second joint has the cylindrical shape. However, the second to fourth implementations below are also applicable.

### Second Implementation

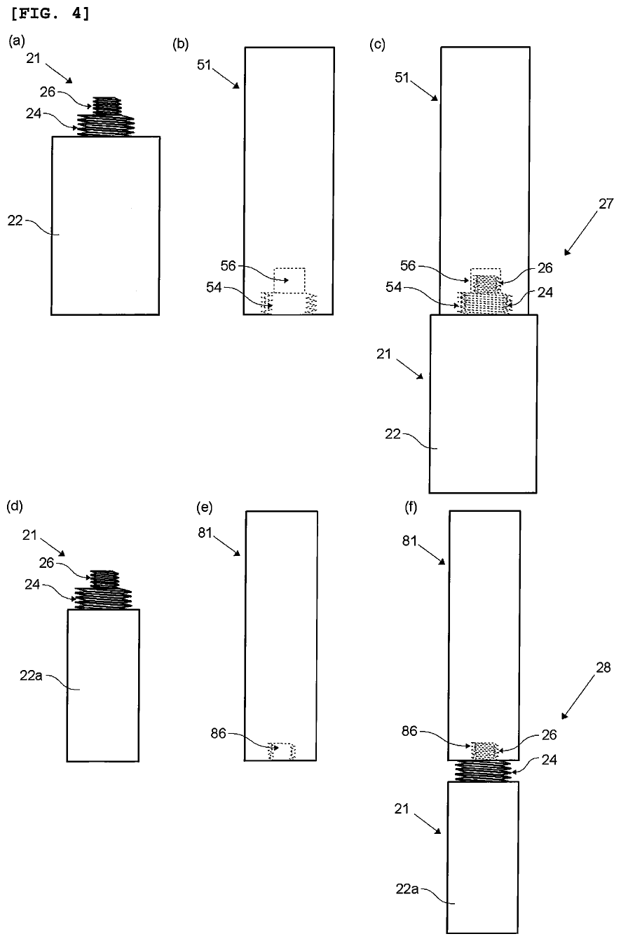

FIG. 4 shows the second implementation of the graphite electrode, the electrode device, and the electrode formed by coupling them of the present invention. In this implementation, both the first joint and the second joint of the graphite electrode have a shape with a screw thread.

A graphite electrode 21 shown in FIG. 4(a) includes a first joint 24 and a second joint 26 adjacent to the first joint 24 in a graphite electrode body 22. These first joint 24 and second joint 26 are coupled to an electrode device (the first electrode device 51 in FIG. 4(b) and a second electrode device 81 in FIG. 4(e) as described later) for energizing the graphite electrode 21. Additionally, as shown in FIG. 4(a), the second joint 26 is smaller than the first joint 24.

Furthermore, the first joint 24 is shaped to be connectable to the first electrode device 51. In the second implementation, as shown in FIG. 4(a), the first joint 24 has a screw thread. The first electrode device 51 shown in FIG. 4(b) is the same as the one in the above first implementation shown in FIG. 3(b), and the concave connecting unit 54 having the female thread shape is formed. The graphite electrode 21 and the first electrode device 51 can be coupled to each other by threadedly coupling the first joint 24 to the concave connecting unit 54 as shown in FIG. 4(c).

Furthermore, the first electrode device 51 can have the space 56 capable of housing the second joint 26 of the graphite electrode 21 as shown in FIG. 4(b). As shown in FIG. 4(c), when coupled via the first joint 24 using the concave connecting unit 54, the first electrode device 51 can house the second joint 26 of the graphite electrode 21 inside the space 56. Therefore, the space 56 is preferably formed to be slightly larger than the second joint 26 of the graphite electrode 21. Additionally, even when the second joint 26 has a shape with a screw thread, the space 56 preferably has a simple shape, for example, a tubular shape, from the viewpoints of a production cost, etc.

As described above, an electrode (first electrode) 27 shown in FIG. 4(c) is configured with the graphite electrode 21 coupled to the first electrode device 51, where the first electrode device 51 is coupled via the first joint 24 of the graphite electrode 21 and has the space 56 capable of housing the second joint 26. Such electrode (first electrode) 27 can be used for arc discharge to produce a quartz glass crucible. After the arc discharge, the graphite electrode body 22 becomes reduced in size due to wear. FIG. 4(d) illustrates a graphite electrode body 22a reduced in size. Additionally, though not shown in FIG. 4(d), as the size becomes smaller, a shape of the graphite electrode body 22a may change.

Moreover, the second joint 26 of the graphite electrode 21 is shaped to be connectable to the second electrode device 81 smaller than the first electrode device 51, as shown in FIG. 4(e). In the second implementation, as shown in FIGS. 4(a) and 4(d), the second joint 26 also has the screw thread, similar to the first joint 24. Additionally, in the second electrode device 81 shown in FIG. 4(e), a concave connecting unit 86 having a female thread shape is formed to be connectable to the second joint 26. The graphite electrode 21 and the second electrode device 81 can be coupled to each other by threadedly coupling the second joint 26 to the concave connecting unit 86 as shown in FIG. 4(f). A second electrode 28 configured with the graphite electrode 21 coupled to the second electrode device 81 can be used for arc discharge to produce a quartz glass crucible.

### Third Implementation

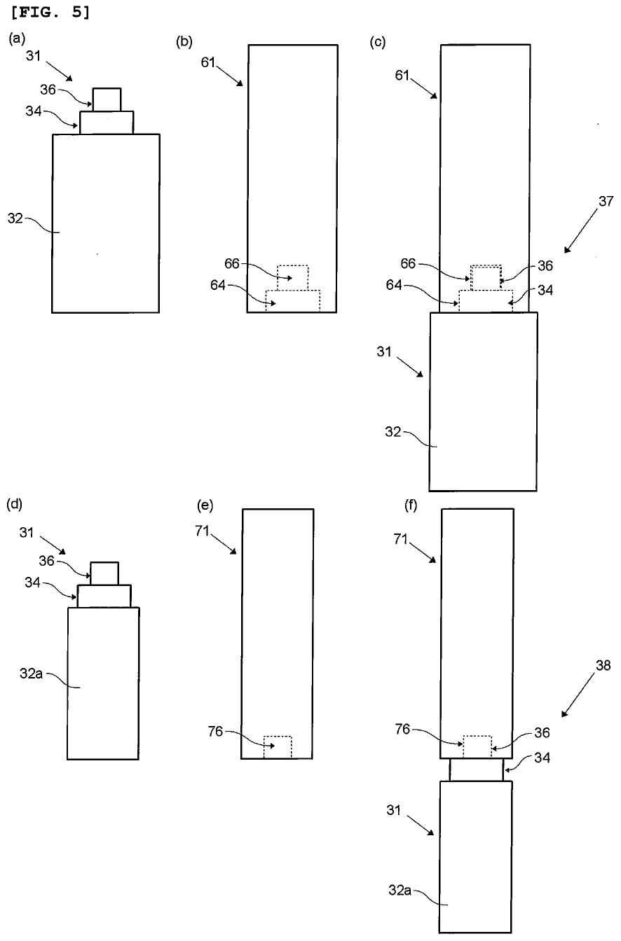

FIG. 5 shows the third implementation of the graphite electrode, the electrode device, and the electrode formed by coupling them of the present invention. In this implementation, both the first joint and the second joint of the graphite electrode have a cylindrical shape. Besides the cylindrical shape, the first joint and the second joint can respectively employ a conical shape, a truncated cone shape, a polygonal prism shape, or the like, but the cylindrical shape is preferable from the viewpoints of a production cost, mechanical strength, and coupling strength.

A graphite electrode 31 shown in FIG. 5(a) includes a first joint 34 and a second joint 36 adjacent to the first joint 34 in a graphite electrode body 32. These first joint 34 and second joint 36 are coupled to an electrode device (a first electrode device 61 in FIG. 5(b) and the second electrode device 71 in FIG. 5(e) as described later) for energizing the graphite electrode 31. Additionally, as shown in FIG. 5(a), the second joint 36 is smaller than the first joint 34.

Furthermore, the first joint 34 is shaped to be connectable to the first electrode device 61. In the third implementation, as shown in FIG. 5(a), the first joint 34 has a cylindrical shape. On the other hand, in the first electrode device 61 shown in FIG. 5(b), a concave connecting unit 64 is formed into a shape that enables the cylindrical first joint 34 to be knocked therein (i.e. a tubular shape). The graphite electrode 31 and the first electrode device 61 can be coupled to each other by, for example, knock-in connection between the first joint 34 and the concave connecting unit 64, as shown in FIG. 5(c).

Furthermore, the first electrode device 61 can have a space 66 capable of housing the second joint 36 of the graphite electrode 31 as shown in FIG. 5(b). As shown in FIG. 5(c), when coupled via the first joint 34 using the concave connecting unit 64, the first electrode device 61 can house the second joint 36 of the graphite electrode 31 inside the space 66. Therefore, the space 66 is preferably formed to be slightly larger than the second joint 36 of the graphite electrode 31.

As described above, an electrode (first electrode) 37 shown in FIG. 5(c) is configured with the graphite electrode 31 coupled to the first electrode device 61, where the first electrode device 61 is coupled via the first joint 34 of the graphite electrode 31 and has the space 66 capable of housing the second joint 36. Such electrode (first electrode) 37 can be used for arc discharge to produce a quartz glass crucible. After the arc discharge, the graphite electrode body 32 becomes reduced in size due to wear. FIG. 5(d) illustrates a graphite electrode body 32a reduced in size. Additionally, though not shown in FIG. 5(d), as the size becomes smaller, a shape of the graphite electrode body 32a may change.

Moreover, the second joint 36 of the graphite electrode 31 is shaped to be connectable to the second electrode device 71 smaller than the first electrode device 61 as shown in FIG. 5(e). In the third implementation, as shown in FIGS. 5(a) and 5(d), the second joint 36 has a cylindrical shape. Additionally, in the second electrode device 71 shown in FIG. 5(e), the concave connecting unit 76 is formed, in which the second joint 36 can be knocked. The graphite electrode 31 and the second electrode device 71 can be coupled to each other by coupling the second joint 36 to the concave connecting unit 76 as shown in FIG. 5(f). A second electrode 38 configured with the graphite electrode 31 coupled to the second electrode device 71 can be used for arc discharge to produce a quartz glass crucible.

### Fourth Implementation

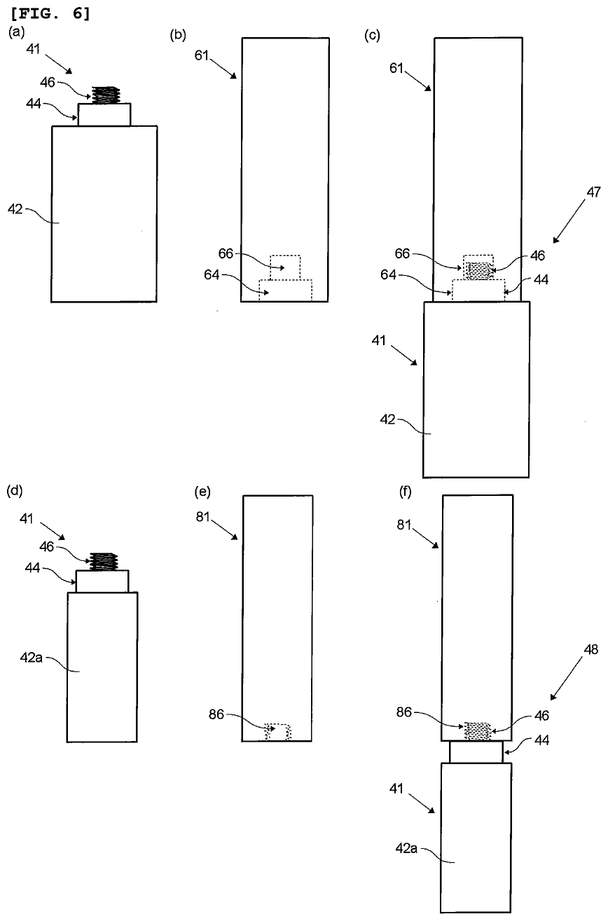

FIG. 6 shows the fourth implementation of the graphite electrode, the electrode device, and the electrode formed by coupling them of the present invention. In this implementation, the first joint of the graphite electrode has a cylindrical shape whereas the second joint has a shape with a screw thread. Besides the cylindrical shape, the first joint can also employ a truncated cone shape, a polygonal prism shape, or the like, but the cylindrical shape is preferable from the viewpoints of a production cost, mechanical strength, and coupling strength.

A graphite electrode 41 shown in FIG. 6(a) includes a first joint 44 and a second joint 46 adjacent to the first joint 44 in a graphite electrode body 42. These first joint 44 and second joint 46 are coupled to an electrode device (the first electrode device 61 in FIG. 6(b) and the second electrode device 81 in FIG. 6(e) as described later) for energizing the graphite electrode 41. Additionally, as shown in FIG. 6(a), the second joint 46 is smaller than the first joint 44.

Furthermore, the first joint 44 is shaped to be connectable to the first electrode device 61. In the fourth implementation, as shown in FIG. 6(a), the first joint 44 has a cylindrical shape. The first electrode device 61 shown in FIG. 6(b) is the same as the one in the above third implementation shown in FIG. 5(b), and the concave connecting unit 64 is formed into a shape that enables the cylindrical first joint 44 to be knocked therein (i.e. a tubular shape). The graphite electrode 41 and the first electrode device 61 can be coupled to each other by, for example, knock-in connection between the first joint 44 and the concave connecting unit 64 as shown in FIG. 6(c).

Furthermore, the first electrode device 61 can have the space 66 capable of housing the second joint 46 of the graphite electrode 41 as shown in FIG. 6(b). As shown in FIG. 6(c), when coupled via the first joint 44 using the concave connecting unit 64, the first electrode device 61 can house the second joint 46 of the graphite electrode 41 inside the space 66. Therefore, the space 66 is preferably formed to be slightly larger than the second joint 46 of the graphite electrode 41. Additionally, even when the second joint 46 has a shape with a screw thread, the space 66 preferably has a simple shape, for example, a tubular shape, from the viewpoints of a production cost, etc.

As described above, an electrode (first electrode) 47 shown in FIG. 6(c) is configured with the graphite electrode 41 coupled to the first electrode device 61, where the first electrode device 61 is coupled via the first joint 44 of the graphite electrode 41 and has the space 66 capable of housing the second joint 46. Such electrode (first electrode) 47 can be used for arc discharge to produce a quartz glass crucible. After the arc discharge, the graphite electrode body 42 becomes reduced in size due to wear. FIG. 6(d) illustrates a graphite electrode body 42a reduced in size. Additionally, though not shown in FIG. 6(d), as the size becomes smaller, a shape of the graphite electrode body 42a may change.

Moreover, the second joint 46 of the graphite electrode 41 is shaped to be connectable to the second electrode device 81 smaller than the first electrode device 61 as shown in FIG. 6(e). In the fourth implementation, as shown in FIGS. 6(a) and 6(d), the second joint 46 has the screw thread. Additionally, in the second electrode device 81 shown in FIG. 6(e), the concave connecting unit 86 having the female thread shape is formed such that the second joint 46 can be coupled thereto, similar to the one in FIG. 4(e) in the second embodiment. The graphite electrode 41 and the second electrode device 81 can be coupled to each other by threadedly coupling the second joint 46 to the concave connecting unit 86 as shown in FIG. 6(f). A second electrode 48 configured with the graphite electrode 41 coupled to the second electrode device 81 can be used for arc discharge to produce a quartz glass crucible.

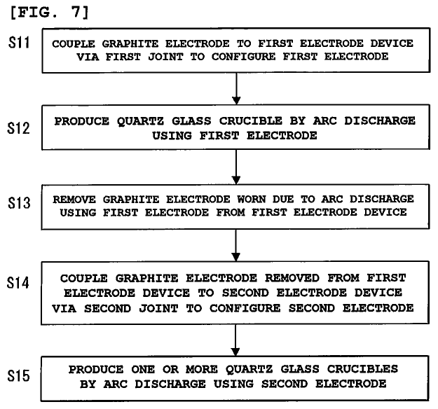

Next, a method for producing a quartz glass crucible by using the graphite electrode of the present invention will be described more specifically. This method is shown in the flow diagram of FIG. 7. While the below description is based on the first implementation shown in FIG. 3, the same applies to the cases of using the graphite electrodes of the second to fourth implementations, except that each employs a different combination of the threaded engagement and the knock-in method as the connection method.

Firstly, the graphite electrode 11 shown in FIG. 3(a) is coupled to the first electrode device 51 shown in FIG. 3(b) via the first joint 14 to configure the first electrode 17 (FIG. 3(c), step S11 in FIG. 7). The coupling herein is the threaded engagement as shown in FIG. 3(c). Further in this event, the second joint 16 of the graphite electrode 11 is housed in the space 56 of the first electrode device 51.

Next, by arc discharge using the first electrode 17, a quartz glass crucible is produced (step S12 in FIG. 7). Here, a specific method for producing the quartz glass crucible is not particularly limited, and a production method of a quartz glass crucible using a graphite electrode can utilize the graphite electrode and the electrode of the present invention.

Next, the graphite electrode 11 worn due to the arc discharge using the first electrode 11 is removed from the first electrode device 51 (step S13 in FIG. 7). In this event, as shown in FIG. 3(d), the graphite electrode body 12a of the first graphite electrode 11 is reduced in size due to wear. Additionally, due to the wear, the shape of the graphite electrode body 12a may change from that of the graphite electrode body 12 before worn.

Next, before coupling the removed graphite electrode 11 to the second electrode device 71, the graphite electrode 11 may be washed as appropriate. Additionally, attached substances such as silica fine particles attached to the surface of the graphite electrode body 12a may be removed. Moreover, if deformation of the graphite electrode body 12a becomes a problem, processing such as shaving down the surface may be performed.

Next, the graphite electrode 11 removed from the first electrode device 51 as shown in FIG. 3(d) is coupled to the second electrode device 71 as shown in FIG. 3(e) via the second joint 16 to configure the second electrode 18 (FIG. 3(f), step S14 in FIG. 7). The coupling herein is by means of the knock-in method as shown in FIG. 3(f).

Next, by arc discharge using the second electrode 18, one or more quartz glass crucibles are produced (step S15 in FIG. 7). When there are no problems, for example, when the graphite electrode 11 is not worn much, after producing one quartz glass crucible, the graphite electrode 11 can directly be used for producing a next quartz glass crucible, thereby producing a plurality of quartz glass crucibles. In this case, a mouth diameter of the quartz glass crucible produced using the second electrode 18 can be made smaller than a mouth diameter of the quartz glass crucible produced using the first electrode 17.

In this manner, the graphite electrode of the present invention can be coupled to different electrode devices to respectively perform arc discharge. Accordingly, it is possible to reuse one graphite electrode to produce a plurality of quartz glass crucibles.

### EXAMPLE

Hereinafter, the present invention will be more specifically described with reference to Examples of the present invention. However, the present invention is not limited to Examples, and various modifications can be made without departing from the technical concept of the present invention.

### Examples 1-1 to 1-6

The graphite electrode 1, the electrode device 5, and the electrode 7 according to the implementation of the present invention shown in FIG. 1 were used to produce a quartz crucible.

Firstly, the graphite electrode 1 as shown in FIG. 1(a) was prepared. The graphite electrode body 2 had a cylindrical shape with a diameter of 80 mm and a length of 300 mm, while the joint 4 had approximately a truncated cone shape (a protrusion called a nipple). The dimensions of the joint 4 in this case are shown in Table 1. The tip diameter in the table refers to the diameter of the tip of the joint 4, the thick portion diameter refers to the diameter at the boundary between the graphite electrode body 2 and the joint 4, and the middle diameter refers to the diameter in the middle of the height (length) from the tip of the joint 4 to the boundary to the graphite electrode body 2.

TABLE 1

| | Dimensions of joint of graphite electrode | | | |
|---|---|---|---|---|
| | Tip | Middle | Thick | |
| | diameter | diameter | portion | Length |
| | [mm] | [mm] | diameter [mm] | [mm] |
| Example 1-1 | 14.0 | 19.0 | 20.6 | 20.0 |
| Example 1-2 | 16.0 | 18.7 | 20.5 | 19.0 |
| Example 1-3 | 15.5 | 18.6 | 20.8 | 20.0 |
| Example 1-4 | 14.6 | 18.8 | 20.7 | 17.0 |
| Example 1-5 | 15.3 | 19.1 | 20.5 | 18.0 |
| Example 1-6 | 18.0 | 19.0 | 20.5 | 16.0 |

Additionally, the electrode device 5 as shown in FIG. 1(b) was prepared.

Next, as shown in FIG. 1(c), the graphite electrode 1 was coupled by the knock-in method via the joint 4 and the hole-shaped holder 6 to configure the electrode 7.

Next, by arc discharge using this electrode 7, a quartz crucible (mouth diameter: 800 mm, 32 inches) was produced.

In all of Examples 1-1 to 1-6, it was possible to produce the quartz crucible in the same manner as a common graphite electrode. Moreover, a production cost for the graphite electrode in Examples 1-1 to 1-6 was about one half of a production cost for a graphite electrode having a screw thread.

### Example 2

The graphite electrode 11 of the first implementation of the present invention shown in FIG. 3 was used to produce a quartz glass crucible according to the flow in FIG. 7.

Firstly, the graphite electrode 11 as shown in FIG. 3(a) was prepared. The graphite electrode body 12 had a cylindrical shape with a diameter of 80 mm and a length of 300 mm, the first joint 14 had a screw thread, and the second joint 16 had a cylindrical shape (a protrusion called a nipple). The second joint 16 was smaller than the first joint 14 as shown in FIG. 3(a).

Additionally, the first electrode device 51 as shown in FIG. 3(b) was prepared. This first electrode device 51 included the concave connecting unit 54 formed into a female thread shape, and had the space 56 adjacent to the concave connecting unit 54.

Next, as shown in FIG. 3(c), the graphite electrode 11 was threadedly coupled to the first electrode device 51 via the first joint 14 and the concave connecting unit 54 to configure the first electrode 17 (step S11 in FIG. 7).

Next, by arc discharge using this first electrode 17, one quartz glass crucible (mouth diameter: 800 mm, 32 inches) was produced (step S12 in FIG. 7).

Next, the graphite electrode 11 worn due to the arc discharge was removed from the first electrode device 51 (step S13 in FIG. 7). After the arc discharge, the graphite electrode body 12a was diminished in size due to wear as shown in FIG. 3(d). Regarding the size of the graphite electrode body 12a, the diameter was about 60 mm and the height was about 200 mm.

Because the removed graphite electrode 11 was too small to be used with the first electrode device 51, it was determined to be used with the second electrode device 71. Attached substances were removed from the removed graphite electrode 11, and the graphite electrode 11 was washed.

Next, the graphite electrode 11 was coupled to the second electrode device 71 as shown in FIG. 3(e) by the knock-in method via the second joint 16 and the concave connecting unit 76 to configure the second electrode 18 as shown in FIG. 3(f) (step S14 in FIG. 7).

Next, by arc discharge using the second electrode 18, one quartz glass crucible (mouth diameter: 600 mm, 24 inches) was produced (step S15 in FIG. 7).

In this manner, it was possible to couple one graphite electrode 11 to the electrode device different from the first electrode device and reuse it for producing the quartz glass crucible.

The present description includes the following embodiments.

[1]: A graphite electrode to be used for arc discharge to produce a quartz crucible, comprising: a graphite electrode body and a joint protruding from the graphite electrode body, the graphite electrode being able to be coupled to an electrode device for energizing the graphite electrode via the joint, wherein the joint is shaped to be knocked in and coupled to the electrode device.

[2]: The graphite electrode according to the above [1], wherein the joint of the graphite electrode has approximately a truncated cone shape having a greater diameter on a side of the graphite electrode body than a diameter on a tip side.

[3]: The graphite electrode according to the above [2], wherein the joint has a height of 10 mm or more and 40 mm or less and has a tapered shape with an angle of 1° or more and 5° or less in a height direction.

[4]: An electrode device capable of holding the graphite electrode according to any one of the above [1] to [3], comprising a hole-shaped holder to be coupled to the joint of the graphite electrode.

[5]: The electrode device according to the above [4], wherein a ratio of an inner diameter of the holder to an outer diameter of the electrode device is 40% or more and 60% or less.

[6]: The electrode device according to the above [4] or [5], wherein a material for the electrode device comprises at least one of gold, silver, copper, and aluminum.

[7]: An electrode configured with the graphite electrode according to any one of the above [1] to [3] coupled to the electrode device.

[8]: A graphite electrode to be used for arc discharge to produce a quartz glass crucible, comprising:
a joint via which the graphite electrode is coupled to an electrode device for energizing the graphite electrode,
wherein the joint comprises a first joint and a second joint different from the first joint,
the second joint is smaller than the first joint,
the first joint is shaped to be connectable to a first electrode device, and
the second joint is shaped to be connectable to a second electrode device smaller than the first electrode device.

[9]: The graphite electrode according to the above [8], wherein the first joint and the second joint each has a shape with a screw thread or a cylindrical shape.

[10]: An electrode configured with the graphite electrode according to the above [8] or [9] coupled to the first electrode device,
wherein the first electrode device is coupled via the first joint of the graphite electrode and has a space capable of housing the second joint.

[11]: A method for producing a quartz glass crucible by using the graphite electrode according to the above [8]or [9], comprising the steps of:
coupling the graphite electrode to the first electrode device via the first joint to configure a first electrode;
producing a quartz glass crucible by arc discharge using the first electrode;
removing the graphite electrode worn due to the arc discharge using the first electrode from the first electrode device;
coupling the graphite electrode removed from the first electrode device to the second electrode device via the second joint to configure a second electrode; and
producing one or more quartz glass crucibles by arc discharge using the second electrode.

It should be noted that the present invention is not limited to the above-described embodiments. The embodiments are just examples, and any examples that substantially have the same feature and demonstrate the same functions and effects as those in the technical concept disclosed in claims of the present invention are included in the technical scope of the present invention.

1-11. (canceled)

12. A graphite electrode to be used for arc discharge to produce a quartz crucible, comprising:
a graphite electrode body and a joint protruding from the graphite electrode body, the graphite electrode being able to be coupled to an electrode device for energizing the graphite electrode via the joint,
wherein the joint is shaped to be knocked in and coupled to the electrode device.

13. The graphite electrode according to claim 12, wherein the joint of the graphite electrode has approximately a truncated cone shape having a greater diameter on a side of the graphite electrode body than a diameter on a tip side.

14. The graphite electrode according to claim 13, wherein the joint has a height of 10 mm or more and 40 mm or less and has a tapered shape with an angle of 1° or more and 5° or less in a height direction.

15. An electrode device capable of holding the graphite electrode according to claim 12, comprising a hole-shaped holder to be coupled to the joint of the graphite electrode.

16. An electrode device capable of holding the graphite electrode according to claim 13, comprising a hole-shaped holder to be coupled to the joint of the graphite electrode.

17. An electrode device capable of holding the graphite electrode according to claim 14, comprising a hole-shaped holder to be coupled to the joint of the graphite electrode.

18. The electrode device according to claim 15, wherein a ratio of an inner diameter of the holder to an outer diameter of the electrode device is 40% or more and 60% or less.

19. The electrode device according to claim 16, wherein a ratio of an inner diameter of the holder to an outer diameter of the electrode device is 40% or more and 60% or less.

20. The electrode device according to claim 17, wherein a ratio of an inner diameter of the holder to an outer diameter of the electrode device is 40% or more and 60% or less.

21. The electrode device according to claim 15, wherein a material for the electrode device comprises at least one of gold, silver, copper, and aluminum.

22. The electrode device according to claim 16, wherein a material for the electrode device comprises at least one of gold, silver, copper, and aluminum.

23. The electrode device according to claim 17, wherein a material for the electrode device comprises at least one of gold, silver, copper, and aluminum.

24. An electrode configured with the graphite electrode according to claim 12 coupled to the electrode device.

25. An electrode configured with the graphite electrode according to claim 13 coupled to the electrode device.

26. An electrode configured with the graphite electrode according to claim 14 coupled to the electrode device.

27. A graphite electrode to be used for arc discharge to produce a quartz glass crucible, comprising:
a joint via which the graphite electrode is coupled to an electrode device for energizing the graphite electrode,
wherein the joint comprises a first joint and a second joint different from the first joint,
the second joint is smaller than the first joint,
the first joint is shaped to be connectable to a first electrode device, and
the second joint is shaped to be connectable to a second electrode device smaller than the first electrode device.

28. The graphite electrode according to claim 27, wherein the first joint and the second joint each has a shape with a screw thread or a cylindrical shape.

29. An electrode configured with the graphite electrode according to claim 27 coupled to the first electrode device,
wherein the first electrode device is coupled via the first joint of the graphite electrode and has a space capable of housing the second joint.

30. An electrode configured with the graphite electrode according to claim 28 coupled to the first electrode device,
wherein the first electrode device is coupled via the first joint of the graphite electrode and has a space capable of housing the second joint.

31. A method for producing a quartz glass crucible by using the graphite electrode according to claim 27, comprising the steps of:
coupling the graphite electrode to the first electrode device via the first joint to configure a first electrode;
producing a quartz glass crucible by arc discharge using the first electrode;
removing the graphite electrode worn due to the arc discharge using the first electrode from the first electrode device;
coupling the graphite electrode removed from the first electrode device to the second electrode device via the second joint to configure a second electrode; and
producing one or more quartz glass crucibles by arc discharge using the second electrode.
